(19) United States
(12) Patent Application Publication
(10) Pub. No.: US 2005/0037626 A1
(43) Pub. Date: Feb. 17, 2005

(54) Semiconductor substrate supporting apparatus

(75) Inventors: Mitsutoshi Shuto, Tokyo (JP); Yasuaki Suzuki, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K./, Tokyo (JP)

(21) Appl. No.: 10/911,813

(22) Filed: Aug. 5, 2004

(30) Foreign Application Priority Data
Aug. 14, 2003 (JP) 2003-293341

(51) Int. Cl. H01L 21/469

(52) U.S. Cl. 438/765

(57) ABSTRACT

A semiconductor substrate supporting apparatus for supporting a single semiconductor substrate in a plasma CVD apparatus comprises a placing block having a substrate placing area on which the substrate is placed. The substrate placing area is anodized and has as an outermost film an anodic oxide film having a thickness of about 30 μm to about 60 μm and/or a dielectric breakdown voltage of about 300 V or higher.

### BACKGROUND OF THE INVENTION

1. Field of the Invention

The present invention relates generally to a semiconductor supporting apparatus for supporting a substrate inside a reaction chamber in a thin-film formation apparatus; and particularly to a semiconductor supporting apparatus which also serves as an electrode inside a reaction chamber in a single-wafer-processing type plasma CVD apparatus.

2. Description of the Related Art

In conventional single-wafer-processing type plasma CVD apparatuses, aluminum or aluminum alloy, which is light weight, excels in thermal conductance and is less likely to cause heavy-metal contamination, has been used as a material for a semiconductor substrate supporting apparatus, which also serves as an electrode. Because an aluminum or aluminum-alloy surface does not always have satisfactory resistance to gas corrosion and plasma, the surface may be anodized. Anodized aluminum or aluminum alloy exhibits better protection from corrosion and plasma.

In conventional semiconductor supporting apparatuses, however, the semiconductor apparatuses are frequently subject to charge-up damage caused by a plasma. Even if anodized aluminum is used, if charge-up on a semiconductor substrate surface increases, leakage current occurs and a large amount of electrical charge passes through the semiconductor apparatus. The semiconductor apparatus may be damaged by leakage current. Leakage current means the electric current caused by electrical charge accumulated on the semiconductor apparatus passing to the grounding potential through the semiconductor substrate supporting apparatus. If the leakage current exceeds a given value, a gate insulation film of the semiconductor apparatus and so forth are deteriorated or broken down, lowering the yield of the semiconductor apparatus.

When surfaces of the conventional semiconductor supporting apparatus are anodized, the anodized surfaces resist electrical charge passing through the semiconductor substrate supporting apparatus. If heated, however, stress caused by a difference between linear thermal expansion coefficients of an aluminum alloy base material and the anodized surface is produced, causing a crack traversing through the anodized surface. This crack facilitates flowing of electrical charge to the grounding potential through the semiconductor substrate supporting apparatus, thereby causing a leakage current increase.

As a countermeasure against these problems, a method using a movable insulating plate was proposed (e.g., Japanese Patent Laid-open No. 2002-134487). Using the insulating plate eliminates leakage current because electric charge accumulated on the semiconductor substrate does not pass through the semiconductor substrate to the grounding potential.

Because thermal conductance is lowered if the insulating plate is used, however, it takes time to raise a temperature of a semiconductor substrate, thereby significantly lowering throughput. Additionally, a substrate temperature becomes substantially lower than a substrate temperature when the substrate is placed on a surface-anodized supporting apparatus; if a heater temperature is raised in order to increase a substrate temperature, temperature control becomes difficult because a temperature difference between a heater and the substrate is great. This makes it difficult to control the properties of a film to be formed in a single-wafer-processing type plasma CVD apparatus, thereby making it impossible to manufacture a semiconductor apparatus as designed. This is an extremely serious problem. Consequently, using the above-mentioned insulating plate is not practical in the single-wafer-processing type plasma CVD apparatus.

### SUMMARY OF THE INVENTION

The present invention was achieved in view of one or more of the above-mentioned problems. In an embodiment, an object of the present invention is to provide an improved semiconductor substrate supporting apparatus with small leakage current and an anodic oxide film resisting dielectric breakdown.

Further, in another embodiment, an object of the present invention is to provide a semiconductor substrate supporting apparatus with excellent substrate temperature controllability and high process stability.

In yet another embodiment, an object of the present invention is to provide a semiconductor substrate supporting apparatus which reduces charge-up damage and improves a yield of processed substrates.

In still another embodiment, an object of the present invention is to provide a semiconductor substrate supporting apparatus which can be manufactured easily and at low cost.

In an additional embodiment, an object of the present invention is to provide a plasma CVD apparatus comprising the semiconductor substrate supporting apparatus and a method of using the same, wherein plasma damage is effectively controlled.

The present invention is not intended to be limited by the above objects, and various objects other than the above can be accomplished as readily understood by one of ordinary skill in the art.

In order to fulfill at least one of the above-mentioned objects, in an embodiment, the present invention provides a semiconductor substrate supporting apparatus for supporting a single semiconductor substrate in a plasma CVD apparatus, comprising a placing block having a substrate placing area on which the substrate is placed, said substrate placing area being anodized and having as an outermost film an anodic oxide film having a thickness of about 30 μm to about 60 μm (including 35 μm, 40 μm, 45 μm, 50 μm, 55 μm, and ranges between any two numbers of the foregoing). In the above, the surface of the substrate placing area is not only anodized but also accumulates a depositing film up to at least about 30 μm. When forming a thin film on the substrate by plasma CVD, plasma damage can effectively be controlled as a function of the thickness of the anodic oxide film.

Further, to fulfill at least one of the aforesaid objects, in an embodiment, the present invention provides a semiconductor substrate supporting apparatus for supporting a single semiconductor substrate in a plasma CVD apparatus, comprising a placing block having a substrate placing area on which the substrate is placed, said substrate placing area being anodized and having as an outermost film an anodic oxide film having a dielectric breakdown voltage of about 300 V or higher (including 350 V, 400 V, 450 V, 500 V, 600 V, 650 V, 700 V, 800 V, 1000 V, and ranges between any two numbers of the foregoing). In the above, the surface of the substrate placing area is not only anodized but also accumulates a depositing film so as to provide a dielectric breakdown voltage of about 300 V or higher. When forming a thin film on the substrate by plasma CVD, plasma damage can effectively be controlled as a function of the dielectric breakdown voltage of the anodic oxide film.

The above embodiments can be combined and further each include the following embodiments:

The anodic oxide film may be constituted by aluminum oxide. The placing block may be constituted by aluminum or an aluminum alloy. The placing block may have a side surface which is anodized and constituted by an anodic oxide film. The side surface of the placing block may not necessarily be provided with an anodic oxide film in order to inhibit plasma damage or leakage current. The anodic oxide film of the side surface may be constituted by aluminum oxide and have a thickness thinner than that of the anodic oxide film in the substrate placing area. In an embodiment, the thickness of the anodic oxide film formed on the side surface may be about 5 μm to about 100 μm, preferably nearly or substantially the same as that of the anodic oxide film in the substrate placing area.

The placing block may have an annular lip portion at its periphery outside the substrate placing area. The annular lip portion may be anodized and has an anodic oxide film as an outermost film. The lip portion of the placing block may not necessarily be provided with an anodic oxide film in order to effectively inhibit plasma damage or leakage current. The anodic oxide film of the side surface may have a thickness thinner than that of the anodic oxide film in the substrate placing area. In an embodiment, the thickness of the anodic oxide film formed in the lip portion may be about 5 μm to about 100 μm, preferably nearly or substantially the same as that of the anodic oxide film in the substrate placing area. In an embodiment, the entire surface of the placing block may be covered with an anodic oxide film except for the bottom surface which may not be exposed to plasmas.

The semiconductor substrate supporting apparatus may further comprise a heating block on which the placing block is mounted. The placing block may have a thickness of about 5 mm to about 15 mm.

In another aspect, the present invention provides a plasma CVD apparatus for processing a single substrate, comprising a reaction chamber and any one of the foregoing semiconductor substrate supporting apparatus disposed in the reaction chamber.

In still another aspect, the present invention provides a method for forming a thin film on a substrate by plasma CVD, comprising: (i) providing any one of the forgoing semiconductor substrate supporting apparatus; (ii) placing a substrate on the substrate placing area of the placing block; and (iii) forming a thin film on the substrate by plasma CVD, wherein plasma damage is controlled as a function of the thickness of the anodic oxide film and/or a function of the dielectric breakdown voltage of the anodic oxide film. Plasma damage can be controlled by correlating the damage with the thickness of the anodic oxide film and/or the dielectric breakdown voltage.

In the foregoing embodiments, any element used in an embodiment can interchangeably be used in another embodiment, and any combination of elements can be applied in these embodiments, unless it is not feasible.

Plasma damage can occur due to various reasons including uneven plasmas, current traversing a wafer laterally, and leakage current. However, among them, leakage current is not well known. An embodiment of the present invention focuses on leakage current. Further, in an embodiment of the present invention, leakage current can be significantly reduced by increasing a dielectric breakdown voltage of the anodic oxide film. Further, in an embodiment of the present invention, a dielectric breakdown voltage is increased by increasing the thickness of the anodic oxide film.

A thick anodic oxide film may cause problems such as increased susceptibility to thermal cracks or detachment and gasification from the surface. In view of the above, the anodic oxide film is formed on a surface of a placing block which supports a single substrate and is disposed in a reaction chamber of plasma CVD. In that case, unlike a thermal CVD apparatus or a batch type plasma CVD apparatus, intense thermal cycles (such as repeating temperature cycles between room temperature and several hundreds centigrade) are not normally used in a single-wafer processing plasma CVD apparatus. The temperature of the placing block is nearly or substantially constant during plasma treatment. Thus, the anodic oxide film may not be subject to thermal shock or stress, and thus, even if the thickness of the anodic oxide film is great such as 30 μm or more, no degradation is likely to occur.

Additionally, in the case of a single-wafer processing plasma CVD apparatus, during plasma treatment, the temperature of the placing block is nearly or substantially constant, and when plasma treatment is discontinued, the chamber is filled with inert gas such as nitrogen (e.g., nitrogen gas flows through the chamber). Thus, once the start-up is accomplished and the system is stabilized, a gasification problem in that gas is generated and released from a surface of a film is unlikely to be caused, even if the thickness of the anodic oxide film is great such as 30 μm or more, no degradation is likely to occur.

For purposes of summarizing the invention and the advantages achieved over the related art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention.

FIG. 1 is a schematic diagram of a plasma CVD apparatus which includes the semiconductor substrate supporting apparatus according to an embodiment of the present invention.

FIG. 2 is a partially enlarged cross section of a preferred embodiment of the semiconductor substrate supporting apparatus according to an embodiment of the present invention.

FIG. 3 is a graph showing the measurement results of leakage current and dielectric breakdown voltage of the semiconductor substrate supporting apparatus according to an embodiment of the present invention.

Explanation of symbols used is as follows: 1: Plasma CVD apparatus; 2: Reaction chamber; 3: Semiconductor substrate supporting apparatus; 4: Showerhead; 5: Gas inlet pipe; 6: Heating block; 7: Placing block; 8: Radio-frequency oscillator; 9: Semiconductor substrate; 10: Matching circuit; 12: Opening portion; 13: Gate valve; 14: Exhaust port; 15: Piping; 16: Conductance regulating valve; 17: Pressure controller; 18: Pressure gauge; 19: Anodic oxide film; 20: Lip; 21: Supporting structure; 22: Heat element; 23: Temperature controller; 24: Ground.

### DETAILED DESCRIPTION OF THE PREFERRED EMBODIMENT

As described above, the present invention includes various embodiments including the following:

The semiconductor substrate supporting apparatus for supporting a semiconductor substrate inside a reaction chamber in a plasma CVD apparatus may comprise a placing block and a heating block and is characterized in that top and side surfaces of the placing block are anodized and a film thickness of an anodic oxide film coated is approximately 30-60 μm.

Specifically, the placing block may comprise an aluminum alloy circular plate having a diameter of approximately 230-350 mm and a thickness of approximately 5-15 mm. Preferably, the placing block may have a lip portion at its periphery. Dielectric breakdown voltage of the anodic oxide film coated is preferably about 300 V or higher. In the above, the thickness of the anodic oxide film may be nearly or substantially uniform or even throughout the substrate placing surface in order to inhibit plasma damage attributable to leakage current. The surface roughness of the anodic oxide film may be of approximately 2-7 μm in an embodiment. However, other portions of the placing block may have various thicknesses of an anodic oxide film.

In these embodiments, by making a film thickness of the anodic oxide film thicker beyond an anodized surface to about 30-60 μm, a dielectric breakdown voltage becomes preferably about 300 V or higher, thereby making it difficult that dielectric breakdown occurs in the anodic oxide film during the plasma process. Additionally, by making a film thickness of the anodic oxide film thicker than the anodized surface, a resistance value of the anodic oxide film becomes larger, thereby enabling to make leakage current smaller. Furthermore, by making a film thickness of the anodic oxide film thicker than the anodized surface, surprisingly, fewer cracks occur; even if a crack occurs, it becomes difficult that the crack reaches the aluminum alloy. As a result, it becomes possible to reduce leakage current.

Because an insulating plate or another ceramic coating is not used, controllability of a semiconductor substrate temperature is excellent; and hence process stability is high.

Further, in an embodiment, charge-up damage is significantly reduced, thereby enabling to improve the yield of the semiconductor apparatus.

Additionally, in an embodiment, production costs of the improved semiconductor supporting apparatus are inexpensive.

Preferred embodiments of the present invention will be described with reference to drawings attached. The present invention should not be limited to the preferred embodiments.

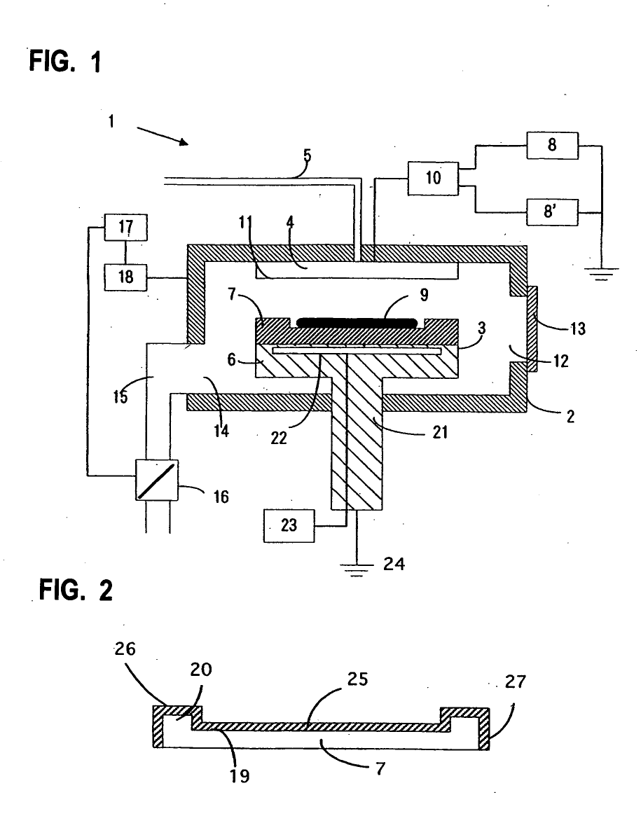

FIG. 1 is a schematic diagram of a single-wafer-processing type plasma CVD apparatus which includes the semiconductor substrate supporting apparatus according to an embodiment of the present invention. The plasma CVD apparatus 1 comprises a reaction chamber 2, a substrate supporting apparatus 3 disposed inside the reaction chamber and used for placing a semiconductor substrate 9 on it, a showerhead 4 set up parallel to and facing the substrate supporting apparatus 3 and used for emitting a jet of a reaction gas uniformly onto the semiconductor substrate 9, an exhaust port 14 for evacuating the inside of the reaction chamber 2 and an opening portion 12 for carrying in and out the semiconductor substrate 9 to and from the reaction chamber 2.

As described below in detail, the substrate supporting apparatus comprises a placing block 7 for placing the semiconductor substrate 9 on it and a heating block 6 for heating the semiconductor substrate 9. The placing block 7 is preferably an aluminum alloy circular plate having a diameter of 230-350 mm and a thickness of 5-15 mm; top and side surfaces of the circular plate are coated with an anodic oxide film. The heating block 6 is preferably an aluminum alloy cylinder having a diameter of 230-350 mm and a thickness of 20-100 mm and is integrated with a supporting structure 21. The supporting structure 21 is grounded 24. The substrate supporting apparatus 3 serves as one side of plasma electrode. The supporting structure 21 is mechanically linked with a drive mechanism (not shown in the figure) for moving the substrate supporting apparatus 3 up and down. A resistance-heating-type heat element 22 is laid buried inside the heating block 6 and is connected to an external temperature controller 23 and a power source (not shown). The heat element 22 is controlled by the temperature controller 23 and heats the semiconductor substrate 9 at a given temperature (e.g., 300-450° C.).

The placing block is preferably constituted by aluminum. Preferably, aluminum has a purity of 96% or higher. For example, as aluminum, A5052 can be used which contains 0.25% or less of Si, 0.40% or less of Fe, 0.10% or less of Cu, 0.1% or less of Mn, 2.2-2.8% of Mg, 0.15-0.35% of Cr, 0.1% or less of Zn, 0.15% or less of other metals, and the remaining of Al. A6061 also can be used which contains 0.4-0.8% of Si, 0.7% or less of Fe, 0.15-0.40% of Cu, 0.15% or less of Mn, 0.8-1.2% of Mg, 0.04-0.35% of Cr, 0.1% or less of Zn, 0.15% or less of Ti, 0.15% or less of other metals, and the remaining of Al.

The anodic oxide film is preferably constituted by aluminum oxide such as Al₂O₃, which is formed by electrolysis on an aluminum surface used as an anode in an electrolyte such as sulfuric acid or oxalic acid, since the placing block is preferably constituted by aluminum as described above. No restriction should be imposed on formation processes of the anodic oxide film. The thickness of an anodic oxide film depositing on an aluminum surface by electrolysis can be determined based on the equation: d=M/6Fρ·I·t, wherein d is thickness of a depositing film, F is Faraday coefficient, ρ is density of Al₂O₃, M is molecular weight of Al₂O₃, I is electric current, and t is time of passing the current. The actual thickness of a depositing anodic oxide film may be slightly thinner than the theoretical value due to a surface dissolving phenomenon of the depositing anodic oxide film. In an embodiment, the conditions of anodic oxidation may be as follows:

Electrolyte: approximately 10-20% of sulfuric acid solution; Current density: D.C. approximately 1-2 A/dm²; Voltage: approximately 10-20 V; Temperature: approximately 20-30° C.; Duration: approximately 20-60 min.; Thickness: approximately 30-60 μm.

The bottom surface of the placing block may not be coated with an anodic oxide film, which can be achieved by using a mask such as an adhesive tape. Also, by covering the side surface of the placing block, it is possible to form an anodic oxide film only on the top surface of the placing block. Further, it is possible to form an anodic oxide film only on a desired surface such as a portion wherein a substrate is placed. The anodic oxide film needs to be formed only on a surface such that an electrical charge does flow through the substrate, although other surfaces can be coated with an anodic oxide film.

The anodic oxide film having a thickness of about 30 μm to about 60 μm has durability and may last until about 10,000-20,000 substrates are processed.

The showerhead 4 is connected to an external reaction gas feed unit (not shown) through a gas inlet pipe 5. At an undersurface 11 of the showerhead 4, thousands of fine pores (not shown) for emitting a jet of reaction gas introduced via the gas inlet pipe 5 onto the semiconductor substrate 9 are provided. The showerhead 4 is electrically connected with radio-frequency oscillators 8, 8′ via a matching circuit 10 disposed outside the reaction chamber and serves as the other side of plasma electrode. The radio-frequency oscillators 8, 8′ generate preferably two different types of RF power of 13.56 MHz and 300-450 kHz respectively. The two types of RF power are synthesized inside the matching circuit 10 and applied to the showerhead.

The exhaust port 14 is linked with an external vacuum exhaust pump (not shown) through piping 15 via a conductance regulating valve 16. The conductance regulating valve 16 is connected with a pressure gauge 18 and a pressure controller 17 and controls a pressure inside the reaction chamber.

A gate vale 13 is provided at the opening portion 12; the reaction chamber is linked with a transfer chamber (not shown) for carrying in/out the semiconductor substrate 9 via the gate valve 13.

FIG. 2 is an enlarged cross section of a preferred embodiment of the placing block 7 in the semiconductor substrate supporting apparatus 3 according to an embodiment of the present invention. The placing block 7 is a nearly circular plate comprising aluminum alloy; its diameter is approximately 230-350 mm, preferably approximately 30-50 mm larger than a diameter of the semiconductor substrate 9; its thickness is approximately 5-15 mm, preferably approximately 7-12 mm. At the periphery of a top surface of the placing block 7, a lip portion 20 is provided. The lip portion 20 is formed so that a top surface 26 of the lip portion becomes nearly or substantially the same height as a surface of the semiconductor substrate 9 when the semiconductor substrate is placed on a placing surface 25 of the placing block 7. In the case of eight-inch wafers, the height may preferably be about 0.5 mm to about 0.75 mm. The gap between the outer periphery of a wafer and the inner periphery of the lip portion may preferably be about 1 mm to about 2 mm. The lip portion 7 serves for preventing concentration of plasma potential applied from the showerhead. The placing surface 25 is formed to be a flat surface with preferably a surface roughness Ra=5 μm (in an embodiment, 1-20 μm, 2-10 μm, or 3-7 μm) in the light of contamination prevention and thermal conductivity.

The top (including the placing surface 25 and the top surface 26 of the lip portion) and side surfaces 27 of the placing block 7 are coated with an anodic oxide film 19 with a thickness of preferably approximately 30-60 μm, more preferably approximately 40-50 μm. In the preferred embodiment shown in FIG. 2, although an undersurface of the placing block 7 is not coated with the anodic oxide film, it can be coated with the anodic oxide film with the same thickness. As a modified version, the placing block can be a simple circular plate not having a lip portion. Additionally, the placing surface 25 can be a spot-faced concave shape, instead of a flat surface. The present invention can be applied to placing block in any shapes. The placing block 7 is removably screwed to the heating block 6. Consequently, for example, by having placing blocks coated with anodic oxide films of different thickness ready, it is possible to use them according to process conditions. As an alternative embodiment, the placing block and the heating block can be integrally formed, instead of being removably fixed to each other.

### EXAMPLES

Measurements conducted for evaluating electrical characteristics of the substrate supporting apparatus according to an embodiment of the present invention are described below. Measurements were made using the substrate supporting apparatuses respectively having anodic oxide film thicknesses of 15 μm, 30 μm and 45 μm. By placing an electrode with a diameter of 0.17 mm over the substrate supporting apparatus and by applying a direct-current voltage of 0-1000 V, a leakage current and a voltage generating dielectric breakdown were measured. Measurement results of leakage current values and dielectric breakdown voltage values are shown in Table 1. Incidentally, in this example, an IV measuring instrument for measuring leakage current for wafers was used, wherein instead of a wafer, a placing block was placed, and instead of a film formed on the wafer, an anodic oxide film formed on the placing block was analyzed.

TABLE 1

| Thickness of | Leakage Current Value | Dielectric |
|---|---|---|
| Anodic Oxide | when 100 V voltage applied | Breakdown |
| Film (μm) | (x E • 08A) | Voltage Value (V) |
| Comparative | 5.77 | 173 |
| Example (15) | | |
| Example 1 (30) | 4.38 | 337 |
| Example 2 (45) | 1.32 | 672 |

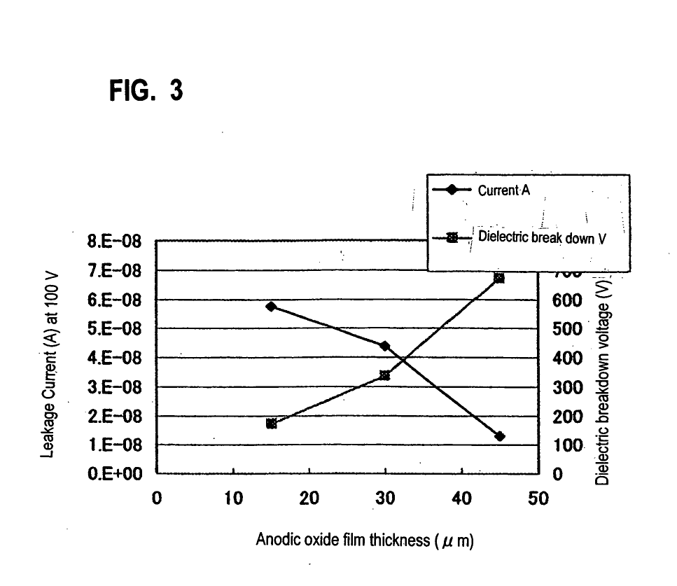

FIG. 3 is a graph made from the measurement results shown in Table 1. As seen from the measurement results, when a film thickness of an anodic oxide film coated on the substrate supporting apparatus increases by twice the thickness of the comparative example, a leakage current value decreases by 24%; when a film thickness increases by three times the thickness of the comparative example, a leakage current value decreases by 75%. This is considered because a resistance value of the anodic oxide film was increased as a film thickness was made thicker. Additionally, when a film thickness of an anodic oxide film coated on the substrate supporting apparatus increases by twice the thickness of the comparative example, a dielectric breakdown voltage value increases by approximately 1.9 times; when a film thickness increases by three times the thickness of the comparative example, a dielectric breakdown voltage value increases by approximately 3.9 times.

The results of actual film formation conducted using the semiconductor substrate supporting apparatuses according to an embodiment of the present invention are described below. Measurements are made using the substrate supporting apparatuses respectively having anodic oxide film thicknesses of 15 μm and 30 μm. After the film formation is finished, film properties of a film formed including a film thickness, uniformity and stress were examined. There were no changes observed between the films formed and a film formed using a comparative substrate supporting apparatus having an anodic oxide film thickness of 15 μm.

Table 2 shows measurement results of the surface potential (V), flat band potential (V) and interface state density (pc./cm²·eV) of test wafers when a comparative substrate supporting apparatus is used and when the substrate supporting apparatus (a thickness of the anodic oxide film was 30 μm) according to an embodiment of the present invention is used. It was seen that values of interface state, flat band potential and interface state density, which are indicators of the degree of plasma damage, are extremely smaller when the substrate supporting apparatus according to an embodiment of the present invention was used than the values when the comparative substrate supporting apparatus was used. This is considered because plasma damage was decreased by using the substrate supporting apparatus according to the embodiment of the present invention.

TABLE 2

| | | | Interface State |
|---|---|---|---|
| | Surface | Flat Band | Density |
| | Potential (V) | Voltage (V) | (pc./cm² • eV) |
| Comparative | 1.45 | −4.1 | 1.3 × 10¹¹ |
| Example | | | |
| Embodiment of | 0.60 | −0.8 | 1.1 × 10¹¹ |
| Present Invention | | | |

Consequently, from the above measurement results, a film thickness of the anodic oxide film of 30 μm or more and dielectric breakdown voltage of 300 V or higher are preferable for the substrate supporting apparatus according to an embodiment of the present invention.

This application claims priority under 35 U.S.C. § 119 to Japanese patent application No. 2003-293341, filed on Aug. 14, 2003, the disclosure of which is incorporated herein by reference in its entirety.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A semiconductor substrate supporting apparatus for supporting a single semiconductor substrate in a plasma CVD apparatus, comprising a placing block having a substrate placing area on which the substrate is placed, said substrate placing area being anodized and having as an outermost film an anodic oxide film having a thickness of about 30 μm to about 60 μm.

2. The semiconductor substrate supporting apparatus according to claim 1, wherein the anodic oxide film is constituted by aluminum oxide.

3. The semiconductor substrate supporting apparatus according to claim 1, wherein the placing block is constituted by aluminum or an aluminum alloy.

4. The semiconductor substrate supporting apparatus according to claim 1, wherein the anodic oxide film has a dielectric breakdown voltage of about 300 V or higher.

5. The semiconductor substrate supporting apparatus according to claim 1, wherein the anodic oxide film has a surface roughness of about 3 μm to 7 μm.

6. The semiconductor substrate supporting apparatus according to claim 1, further comprising a heating block on which the placing block is mounted.

7. The semiconductor substrate supporting apparatus according to claim 6, wherein the placing block has a thickness of about 5 mm to about 15 mm.

8. The semiconductor substrate supporting apparatus according to claim 1, wherein the placing block has a side surface which is anodized and constituted by an anodic oxide film.

9. The semiconductor substrate supporting apparatus according to claim 8, wherein the anodic oxide film of the side surface is constituted by aluminum oxide and has a thickness of 30 μm to 60 μm.

10. The semiconductor substrate supporting apparatus according to claim 1, wherein the placing block has an annular lip portion at its periphery outside the substrate placing area.

11. The semiconductor substrate supporting apparatus according to claim 10, wherein the annular lip portion is anodized and has an anodic oxide film as an outermost film.

12. The semiconductor substrate supporting apparatus according to claim 11, wherein the anodic oxide film in the lip portion has a thickness of 30 μm to 60 μm.

13. A plasma CVD apparatus for processing a single substrate, comprising a reaction chamber and the semiconductor substrate supporting apparatus of claim 1 disposed in the reaction chamber.

14. A method for forming a thin film on a substrate by plasma CVD, comprising:
providing the semiconductor substrate supporting apparatus of claim 1;
placing a substrate on the substrate placing area of the placing block; and
forming a thin film on the substrate by plasma CVD, wherein plasma damage is controlled as a function of the thickness of the anodic oxide film.

15. The method according to claim 14, wherein the dielectric breakdown voltage of the anodic oxide film is about 300 V or higher.

16. The method according to claim 14, wherein plasma damage is further controlled as a function of the dielectric breakdown voltage of the anodic oxide film.

17. A semiconductor substrate supporting apparatus for supporting a single semiconductor substrate in a plasma CVD apparatus, comprising a placing block having a substrate placing area on which the substrate is placed, said substrate placing area being anodized and having as an outermost film an anodic oxide film having a dielectric breakdown voltage of 300 V or higher.

18. The semiconductor substrate supporting apparatus according to claim 17, wherein the anodic oxide film is constituted by aluminum oxide.

19. The semiconductor substrate supporting apparatus according to claim 17, wherein the placing block is constituted by aluminum or an aluminum alloy.

20. The semiconductor substrate supporting apparatus according to claim 17, wherein the placing block has an annular lip portion at its periphery outside the substrate placing area.

21. The semiconductor substrate supporting apparatus according to claim 20, wherein the annular lip portion is anodized and has an anodic oxide film as an outermost film.

22. A plasma CVD apparatus for processing a single substrate, comprising a reaction chamber and the semiconductor substrate supporting apparatus of claim 17 disposed in the reaction chamber.

23. A method for forming a thin film on a substrate by plasma CVD, comprising:
providing the semiconductor substrate supporting apparatus of claim 17;
placing a substrate on the substrate placing area of the placing block; and
forming a thin film on the substrate by plasma CVD, wherein plasma damage is controlled as a function of the dielectric breakdown voltage of the anodic oxide film.
